(19) United States
(12) Patent Application Publication
(10) Pub. No.: US 2008/0283980 A1
(43) Pub. Date: Nov. 20, 2008

(54) LEAD FRAME FOR SEMICONDUCTOR PACKAGE

(75) Inventors: Wei Gao, Tianjin (CN); Zhi-Gang Bai, Tianjin (CN); Li-Wei Liu, Tianjin (CN); Zhi-Jie Wang, Tianjin (CN); Yuan Zang, Tianjin (CN); Hong Zhu, Tianjin (CN)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: FREESCALE SEMICONDUCTOR, INC, Austin, TX (US)

(21) Appl. No.: 12/099,794

(22) Filed: Apr. 9, 2008

(30) Foreign Application Priority Data
May 18, 2007 (CN) 200710105012.0

(51) Int. Cl. H01L 23/495; H01R 43/00; H01L 21/60

(52) U.S. Cl. 257/670; 29/874; 438/123; 257/E23.031; 257/E21.506

(57) ABSTRACT

A lead frame (10) for a quad flat non-leaded semiconductor package (606), includes a tie bar (12), a first group of leads (22) extending a first length from the tie bar (12) in a transverse direction (Y), and a second group of leads (24) extending a second length from the tie bar (12) in the transverse direction (Y). The second length is greater than the first length, and leads from the first and second group of leads (22, 24) alternate in a longitudinal direction (X) along the tie bar (12) so that the first and second groups of leads are staggered. The second group of leads (24) is displaced from the first group of leads (22) in a Z-direction (Z) perpendicular to both the transverse (Y) and longitudinal (X) directions. The leads of the first and second groups of leads (22, 24) each have a respective contact terminal (26 and 28) at their distal ends. The contact terminals (26 and 28) each have a contact face (40 and 42) in a contact plane (44).

### BACKGROUND OF THE INVENTION

The present invention relates to the field of semiconductor packaging, and in particular though not exclusively to quad flat non-leaded (QFN) packaging.

Semiconductor packages use lead frames to position leads in order to electrically couple a semiconductor die or integrated circuit (IC) to respective external terminals, pins or contact pads for connecting to a printed circuit board (PCB) Conventional lead frames are formed on a metal strip that may be sawn or molded to form a number of leads corresponding to external electrical contacts. The semiconductor die or IC is positioned adjacent the leads that are held in position by the lead frames. Contacts on the semiconductor die are electrically coupled to respective leads such as with wire bonds. The semiconductor die and lead frames are then encapsulated in a plastic packaging material, and the lead frames are sawn or cut to singulate the leads in order to generate the final semiconductor package. The leads may extend outside the packaging material, or in the case of surface mounted chips, a surface of the leads is exposed at the bottom of the semiconductor package for electrical connection to the PCB. An example surface mounted chip package is the quad flat non-leaded (QFN) package, which includes exposed contact pads or terminals underneath and on four sides of a rectangular semiconductor package.

Increasing miniaturization requires greater contact or terminal densities, typically requiring smaller lead and terminal widths and pitches. However such small dimensioned leads can result in manufacturing problems. In one type of QFN lead frame, a tie bar is used with inner and outer leads extending from the same side. These inner and outer leads are staggered or alternated along the lead frame in order to provide two rows of lead contacts underneath and on each side of the packaged semiconductor. Such an arrangement avoids the need for the half-saw process for separating the tie bar from the leads whilst avoiding cutting the bonding wires to the outer leads. However the inner leads tend to be long and thin and therefore more susceptible to dislodging during the full saw or singulation process. In another type of lead frame for QFN packages, a tie bar is formed with inner and outer leads extending from opposite sides of the tie bar. Whilst this reduces the length of the leads, the tie bar must be half-sawn in order to avoid cutting the bonding wires. This half-saw process is difficult to implement successfully in smaller and smaller dimensioned semiconductor packages.

### BRIEF DESCRIPTION OF THE DRAWINGS

For the purpose of illustrating the invention, there are shown in the drawings embodiments which are presently preferred. It should be understood, however, that the invention is not limited to the precise arrangements and instrumentalities shown. Elements in the figures are illustrated for simplicity and clarity and have not necessarily been drawn to scale. In the drawings:

FIG. 1 is an enlarged, top plan view of a lead frame in accordance with an embodiment of the present invention;

FIG. 2 is an enlarged partial top plan view of a portion of the lead frame of FIG. 1;

FIG. 3 is an enlarged cross-sectional view of a portion of the lead frame of FIG. 1;

FIG. 4 is an enlarged perspective view of a portion of the lead frame of FIG. 1;

FIG. 5 is an enlarged cross-sectional view of a portion of a lead frame according to another embodiment of the present invention;

FIG. 6 is an enlarged top plan view of a portion of the lead frame of FIG. 5;

FIG. 7 is an enlarged cross-sectional view of a chip package before encapsulation and singulation according to an embodiment of the present invention;

FIG. 8 is an enlarged cross-sectional view of the chip package of FIG. 7 following encapsulation and singulation;

FIG. 9 is an enlarged bottom plan view of the chip package of FIG. 7; and

FIG. 10 is a flow chart of a method of manufacturing a chip package according to an embodiment of the present invention.

### DETAILED DESCRIPTION OF EMBODIMENTS OF THE INVENTION

In general terms, the present invention is a lead frame for a quad flat non-leaded (QFN) semiconductor package. The lead frame is typically formed as an array of lead frames. However, as is known by those of skill in the art, sometimes strips of lead frames are formed too. Thus, the present invention is not to be limited to either strips or arrays. In one embodiment, the present invention is a lead frame for a quad flat non-leaded (QFN) semiconductor package, including a tie bar; a first group of leads having a first length and extending from the tie bar in a transverse direction; a second group of leads having a second length and extending from the tie bar in the transverse direction, wherein the second length is greater than the first length. The leads from the first and second groups alternate in a longitudinal direction along the tie bar so that the first and second groups of leads are staggered. Further, the second group of leads is displaced from the first group of leads in a z-direction perpendicular to both the transverse and longitudinal directions. The leads of the first and second groups each have a respective contact terminal at their distal ends. The contact terminals each have a contact face in a contact plane.

In the presently preferred embodiment, the z-direction displacement is achieved by half-etching both groups of leads, with the first group being half-etched on a first side and the second group being half-etched on a second side that is opposite the first side.

By staggering and displacing adjacent leads in the z-direction, more leads may be located around a die without compromising lead strength. That is, while lead pitch is increased, the width of the individual leads does not have to be decreased. The displacement in the z-direction between adjacent leads also reduces the likelihood of short circuits between these leads.

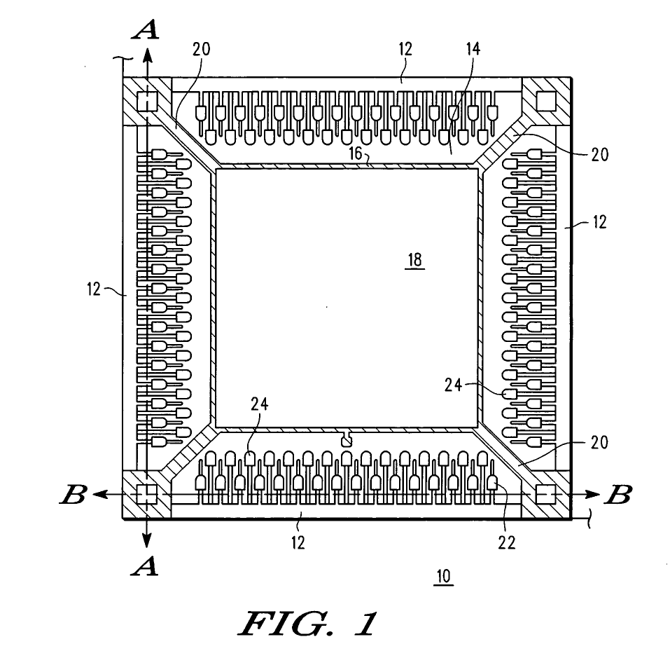

Referring now to the drawings, wherein like numbers refer to like elements, FIG. 1 shows a metal lead frame 10. The lead frame 10 includes a plurality of tie bars 12 that give the lead frame 10 a generally square or rectangular shape. As discussed above, the lead frame 10 may be formed in an array of lead frames, such as a 3×3 or 4×4 array. Each lead frame 10 is suitable for packaging one or more semiconductor die. That is, while the lead frame 10 typically will be used to package a single die, multiple dies could be stacked one on another, so the lead frame 10 could be used with stacked dies too.

The tie bars 12 form a planar or two-dimensional (2D) rectangle with a cavity 14, as shown. The cavity 14 may be an open cavity or include a die pad or flag 16 for receiving a die 18. As is known by those of skill in the art, in an open cavity design, a finished package will have an exposed die, while in a design with a flag, the flag is exposed. The lead frame 10 has support bars 20 that extend from the corners thereof to the flag 16 for holding the flag 16 in place with respect to the lead frame 10.

The lead frame 10 has a first group of leads 22 (also referred to herein as first leads 22) that extend perpendicularly from the tie bars 12 to which they are attached. That is, the first leads 22 extend in a transverse direction, which is towards the cavity 14. The first leads 22 have a first length. A second group of leads 24 (also referred to herein as second leads 24) also extends from the tie bars 12 in the transverse direction. The second leads 24 have a second length that is greater than the first length. The first leads 22 correspond to outer leads or contact terminals for the finished semiconductor package and the second leads 24 correspond to inner leads or contact terminals for the finished semiconductor package. As the second leads 24 are longer than the first leads 22, the second leads 24 are thus closer to the die 18. As will be discussed in more detail later, during assembly, the first and second leads 22 and 24 are separated from the tie bars 12, typically via sawing. FIG. 1 shows two lines A-A and B-B, called saw streets, along which a saw is run to separate the leads 22 and 24 from the tie bars 12. After singulation (sawing), the leads 22 and 24 are electrically isolated from each other.

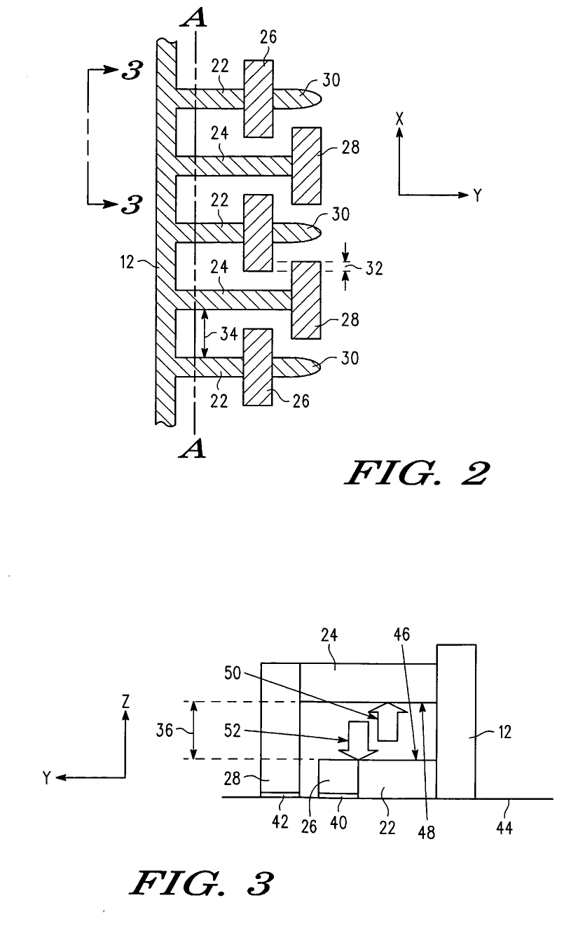

Referring now to FIG. 2, one of the tie bars 12 is shown with the first and second leads 22 and 24 extending in a transverse direction therefrom (Y direction). The first and second leads 22 and 24 alternate in a longitudinal direction along the tie bar 12 (X direction) so that the first and second leads 22 and 24 are staggered.

The first and second leads 22 and 24 have respective contact terminals 26 and 28 integrally formed at their distal ends. Although the contact terminals 26 and 28 are shown as rectangular in shape, the contact terminals 26 and 28 could have other shapes, such as circular, semicircular or arcuate. In addition, the contact terminals 26 of the first leads 22 have flashing 30 that extends outwardly in the transverse direction (x direction). The flashing 30 is beneficial for assisting in securing mold compound or plastic packaging material to the leads 22. The contact terminals 26 and 28 of adjacent ones of the first and second leads 22 and 24 may overlap one another, in the longitudinal direction (X), as indicated by overlap 32. The overlap 32 enables a greater density of or smaller pitch for the contact terminals 26 and 28 on the finished semiconductor package. Thus a greater number of contact terminals 26 and 28 of a given size may be included within a given longitudinal length (X) of the lead frame 10. This aids in further miniaturization of such chips. The first and second leads 22 and 24 are also spaced from each other in the longitudinal (X) direction as indicated by arrow 34. FIG. 2 also shows the saw street A-A.

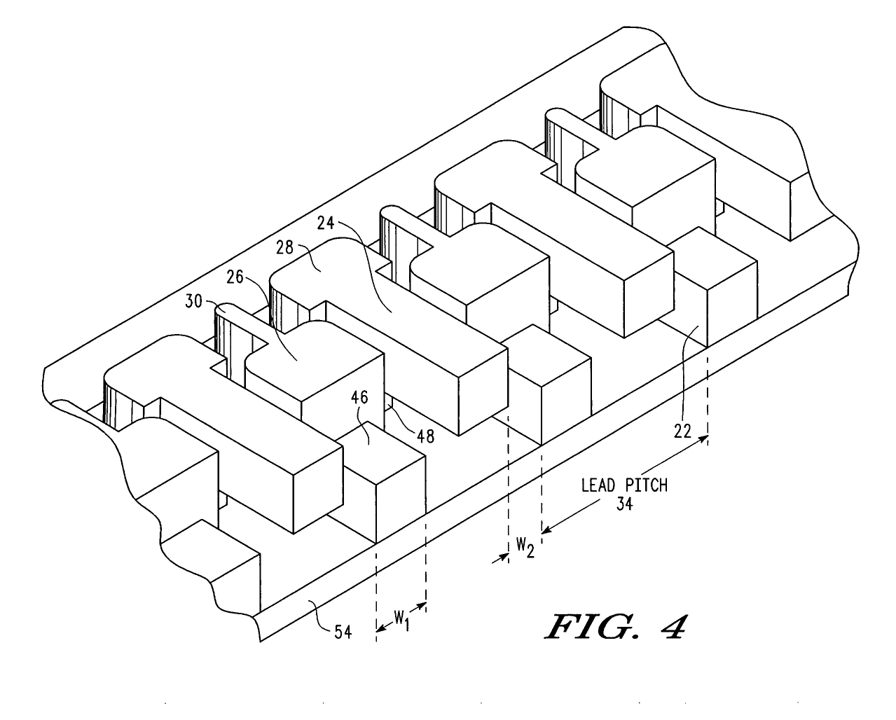

FIG. 3 illustrates a cross-sectional view of a portion of the lead frame 10 shown in FIG. 2 along lines 3-3. The tie bar 12, one of the first leads 22 and one of the second leads 24 are shown. The first and second leads 22 and 24 are displaced in a Z-direction with respect to each other, as indicated by Z-displacement 36. The 2-direction is perpendicular to both the transverse (Y) and longitudinal (X) directions of the lead frame 10. The Z-displacement 36 of the first and second leads 22 and 24 ensures that adjacent outer and inner leads 22 and 24 are electrically isolated from each other following singulation, which separates the leads 22, 24 from the tie bar 12.

The contact terminals 26 and 28 of the leads 22, 24 include respective contact faces or sides 40 and 42 in a contact plane 44. The contact faces 40 and 42 correspond to the exposed terminals or contact pads following assembly and singulation of the completed semiconductor package. The contact faces 40 and 42 enable the semiconductor die 18 to be electrically connected to a printed circuit board onto which it will be mounted.

The Z-displacement 36 may be formed by any suitable manufacturing step such as pre-forming the metal strip or preferably by half-etching the leads 22, 24. Half-etching is a process in which a part of the metal area is etched away in order to reduce the thickness of that area. Half-etching may reduce the metal area's thickness by half or some other fraction between the original metal thickness and zero thickness. In the embodiment shown, the half-etching process is performed on both groups of leads 22, 24 in the Z-direction, but from opposite sides. More specifically, the first or outer leads 22 include a first side 46 in the Z-direction, while the second or inner lead 24 includes a second side 48 in the Z-direction. The second side 48 is opposite to the first side 46. Half-etching is applied to the opposite sides 46, 48 of adjacent leads 22 and 24 as indicated by half-etching direction arrows 50 and 52. Thus first half-etching 50 is applied to the first sides 46 of the first or outer leads 22 in order to reduce their thickness. Then second half-etching 52 is applied to the second sides 48 of the second or inner leads 24 in order to reduce their thickness. The half-etching results in the displacement 36 in the Z-direction as shown. The order of the half-etching may be reversed.

FIG. 4 is an enlarged perspective view of the portion of the lead frame 10 shown in FIG. 2 and illustrates the half-etching of the first and second leads 22 and 24. As shown, the first side 46 of the first leads 22 is half-etched and a first side 48 of the second leads 24 is half-etched. The first side 48 of the second leads 24 is opposite facing to the first side 46 of the first leads 22. Note that the leads 22 and 24 have a width W₁ that is less than a width of the contact terminals 26 and 28. A half of the additional width of the contact terminals is indicated as W₂. The lead pitch is indicated at 34.

FIG. 4 also illustrates an important feature of the invention, namely that the contact terminals 26 and 28 of the first and second leads 22 and 24 lie in the same plane. Having the contact terminals 26 and 28 in the same plane allows the contact terminals 26 and 28 to be attached to a tape 54. Having the contact terminals 26 and 28 in a single plane also allows the lead frame 10 to be used for various leadless package types, like QFN, PQFN, and MLF. During assembly, all of the contact terminals 26 and 28 sit on the tape 54, which enables wire bonding to be performed. Further, after molding, all of the contact faces 40 and 42 are exposed at a bottom of the package and lie in one plane.

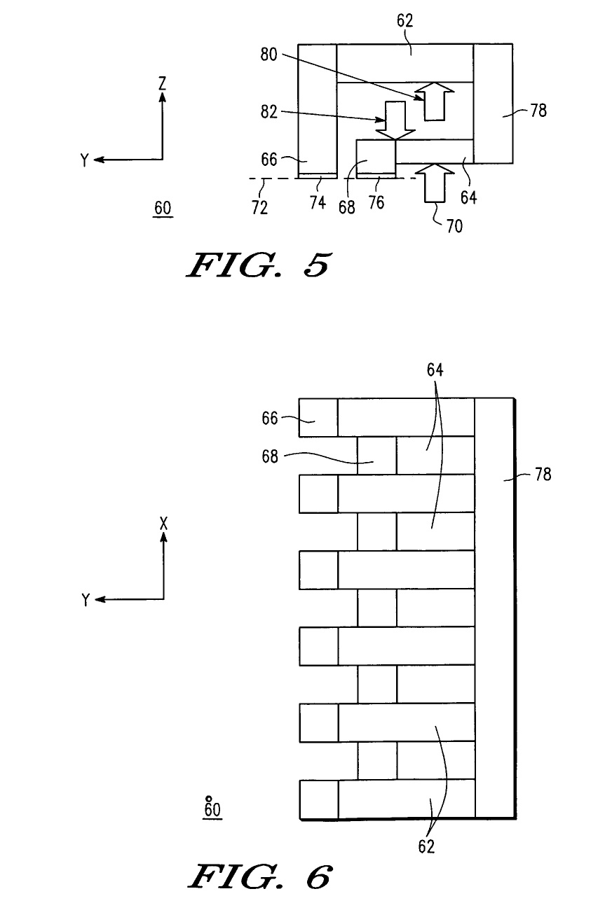

FIGS. 5 and 6 show section and top views respectively of a part of a lead frame 60 in accordance with another embodiment of the invention. The lead frame 60 is similar to the lead frame 10 of FIGS. 1-4, however the inner and outer leads 62 and 64 are the same longitudinal (X) width as their respective contact terminals 66 and 68. Additionally, there is no longitudinal (X) displacement (e.g., 34 in FIG. 2) between adjacent leads 62 and 64. Furthermore there is no longitudinal (X) overlap (e.g., 32 in FIG. 2) between the contact terminals 66 and 68 of adjacent leads 62 and 64.

In the Z-direction, an additional half-etching process indicated by arrow 70 (FIG. 5) has been performed in order to etch the bottom or second side of the outer lead 62 away from a contact plane 72 of respective contact faces 74 and 76 of the contact terminals 66 and 68 of the leads 62 and 64. This limits metal exposure from the finished chip package to the contact faces 74 and 76. As with the lead frame 10, the leads 62 and 64 project outwardly from a tie bar 78. The arrows 80 and 82 indicate the half-etching that is performed on the leads 62 and 64, respectively.

Various alternative arrangements that alter the half-etching and/or respective dimensions of the leads 12 and 14 and their contact terminals 16 will be appreciated by those skilled in the art.

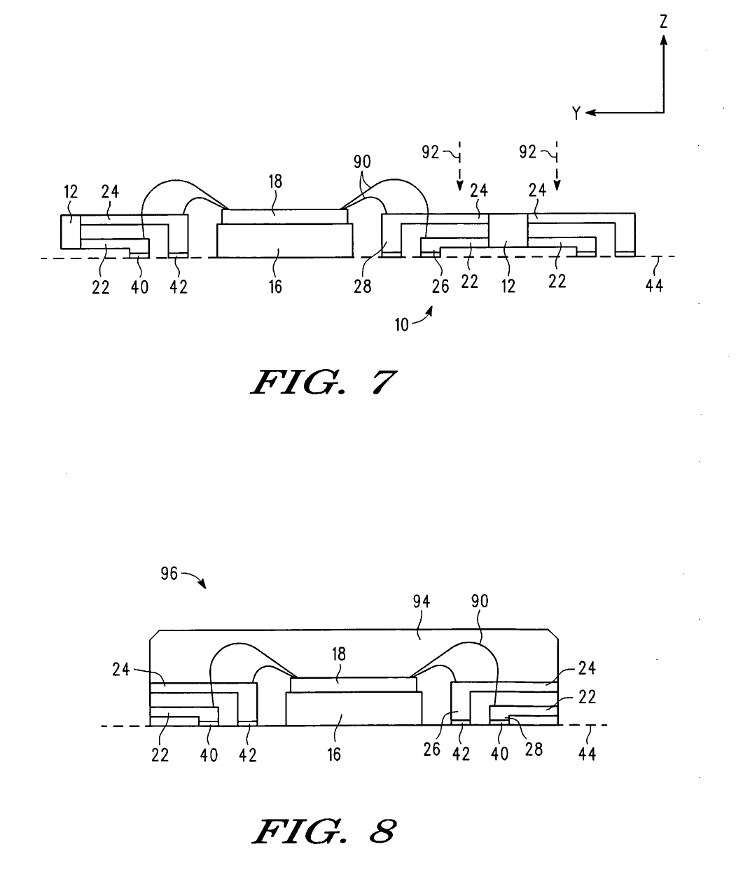

FIG. 7 shows a partial cross-sectional view of the lead frame 10 of FIG. 1 including the tie bar 12, first and second leads 22, 24 which are displaced with respect to each other in the Z-direction, flag 16 and semiconductor die 18. The die 18 is attached to the flag 16 with an adhesive as is known by those of skill in the art. Pads on a top surface of the die 18 are electrically connected to the contact terminals 26 and 28 of the first and second leads 22 and 24 with bond wires 90 as shown. Saw streets are shown with arrows 92. The saw streets will result in separation of the leads 22 and 24 from the tie bars 12. Prior to this singulation operation however, the first and second leads 22 and 24, bond wires 90, flag 16 and semiconductor die 18 are encased or encapsulated with a plastic or other insulating packaging material (mold compound) 94 (FIG. 8).

FIG. 8 shows a finished chip or semiconductor package 96 following encapsulation with a packaging material 94 and singulation. It can be seen that the tie bars 12 have been removed by the saw singulation process, and that the contact faces 40 and 42 of the contact terminals 26 and 28 of the first and second leads 22 and 24 are exposed from the packaging material 94 at the bottom of the semiconductor package or chip 96.

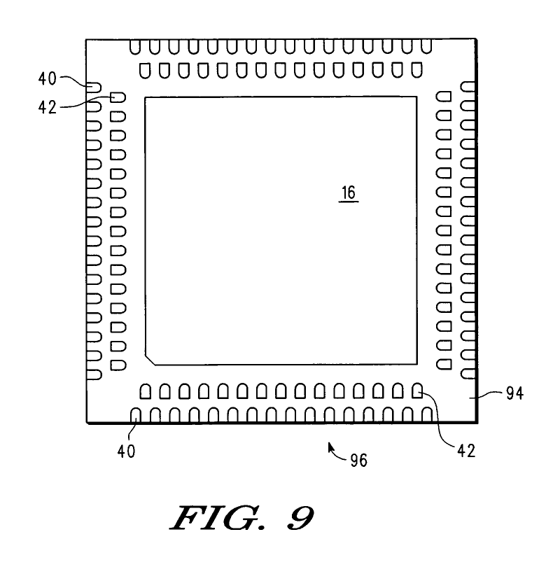

FIG. 9 shows a bottom plan view of the finished chip 96. Staggered rows of inner and outer contact faces 40 and 42 can be seen along the four sides of the package 96. Inner contact faces 40 corresponding to the inner leads 22 are separated from the outer contact faces 42 of the outer leads 24. The leads 22, 24 are retained inside the package 96 but are electrically separated from each other by the Z-displacement shown in FIGS. 3-5. It can be seen that by providing inner and outer contact faces 40 and 42 that are not separated in the longitudinal direction (X) of each side of the package 96, the density of contact faces per package is increased, and similarly the contact face pitch is reduced. In other embodiments where adjacent inner and outer contact faces or pads 40 and 42 overlap in the longitudinal direction (X), higher density of contact faces is achieved while still being able to increase the size of the contact faces 40 and 42 for improved electrical connection to a PCB.

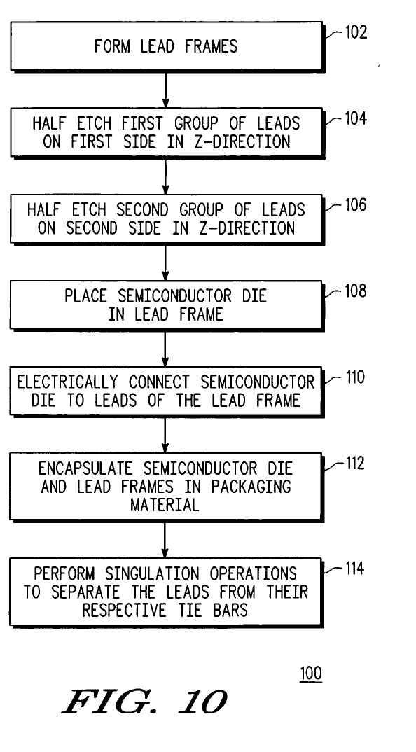

FIG. 10 shows a method of manufacturing a chip or semiconductor package (96) according to an embodiment of the present invention. In the method 100, an array of lead frames are formed from a bare metal sheet such as by cutting, stamping and/or etching, as is known by those of skill in the art, at step 102. Individual lead frames are connected to each other via tie bars (12).

The lead frames are of the staggered inner and outer QFN type as previously described. Each lead frame (10) has a plurality of tie bars (12) that have first and second groups of leads (22, 24) extending therefrom, where the first leads project a first length from the tie bar in a transverse direction (Y) and the second leads project a second length from the tie bar in the transverse direction (Y), the second length being longer than the first length. The leads (22, 24) from the first and second group of leads alternate in a longitudinal direction (X) along the tie bar (12) so that the first and second groups of leads are staggered. The leads have contact terminals (26 and 28) at their distal ends. The contact terminals (26 and 28) each have a contact face (40 and 42) in a contact plane (44). The contact terminals (26 and 28) are typically integral with their respective leads (22, 24), and may be of the same or different longitudinal (X) width.

After forming the lead frames, the first group of leads (22) is half etched on one side in a Z-direction at step 104. The Z-direction is perpendicular to the longitudinal (X) and the transverse (Y) directions of the lead frame and metal strip (XY) plane. Typically the half-etching will result in less than half the (Z) depth of these outer leads remaining.

The second group of leads (24) is then half etched on the other side in the Z-direction at step 106. The other side of these inner leads is opposite the side of the outer leads that was half-etched at step 104. Typically the half-etching will result in less than half the (Z) depth of these inner leads remaining. Thus the inner and outer leads 22 and 24 are displaced in the Z-direction as shown in FIG. 3. Note also that the leads 22 and 24 are etched but not the contact terminals 26 and 28 of the leads, which allows the contact faces 40 and 42 to lie in the same plane 44 (and to be attached to the tape 54 during assembly).

The semiconductor die (18) is then placed within the cavity (14) formed by the four tie bars (12) of a lead frame at step 108. Where the lead frame includes a die pad (16), the semiconductor die is mounted on and attached to the die pad as will be appreciated by those skilled in the art.

Pads on the semiconductor die are then electrically connected to the contact terminals (26 and 28) at step 110. This is typically achieved using gold bond wires connecting semiconductor die pads to respective contact terminals (26 and 28) as would be appreciated by those skilled in the art.

The lead frame 10, including first and second leads 22, 24, die pad 16, die 18 and wires 90 are then encapsulated in a packaging material (94) at step 112. The encapsulation or molding process is controlled such that the contact faces 40 and 42 are exposed from the package. For example, the lead frame 10 may rest on a tape during the assembly process, with the tape being removed either before or after a singulation step 114. The packaging material is typically a plastic material, and the encapsulation process, also called molding, will be appreciated by those skilled in the art.

The encapsulated lead frame array is then singulated at step 114. This singulation operation typically involves a saw cut along a number of saw streets in order to separate the inner and outer leads from their respective tie bars and to define individual semiconductor devices, chips or packages, as illustrated in FIG. 8. The saw cuts completely through the metal parts of the leads and packaging material (94). A benefit of the half-etched leads 22 and 24 is that the saw does not have to cut as deeply and cuts less metal, thus the life of the saw blade will be longer than if the saw had to cut through unetched leads.

Whilst the embodiments have been described with respect to half-etching the Z-displacement between the first and second groups of leads (22, 24), other manufacturing steps could alternatively be used. Similarly, while the contact terminals have been described as being integral with their respective leads, alternative manufacturing steps could be performed as would be appreciated by those skilled in the art.

The skilled person will also appreciate that the various embodiments and specific features described with respect to them could be freely combined with the other embodiments or their specifically described features in general accordance with the above teaching. The skilled person will also recognize that various alterations and modifications can be made to specific examples described without departing from the scope of the appended claims.

1. A lead frame for a quad flat non-leaded (QFN) semiconductor package, comprising:
a tie bar;
a first group of leads extending a first length from the tie bar in a transverse direction;
a second group of leads extending a second length from the tie bar in the transverse direction, the second length being greater than the first length;
wherein leads from the first and second groups of leads alternate in a longitudinal direction along the tie bar so that the first and second group of leads are staggered;
wherein the second group of leads is displaced from the first group of leads in a z-direction perpendicular to both the transverse and longitudinal directions; and
the leads of the first and second groups of leads each having a respective contact terminal at their distal ends, said contact terminals each having a contact face in a contact plane.

2. The lead frame of claim 1, wherein the first group of leads is half-etched in the z-direction on a first side thereof and the second group of leads is half-etched in the z-direction on a second side thereof that is opposite the first side.

3. The lead frame of claim 1, wherein the contact terminals of adjacent leads of the first and second groups of leads overlap in the longitudinal direction.

4. The lead frame of claim 1, wherein adjacent leads of the first and second groups of leads are spaced from each other in the longitudinal direction.

5. The lead frame of claim 1, wherein the contact terminals have a longitudinal length greater than the longitudinal length of their respective leads.

6. The lead frame of claim 1, wherein the first group of leads includes flashing that extends from the contact terminals in the transverse direction.

7. A method of manufacturing a lead frame for a quad flat non-leaded (QFN) semiconductor package, the method comprising:
forming in a metal strip a tie bar having a first group of leads extending a first length from the tie bar in a transverse direction and a second group of leads extending a second length from the tie bar in the transverse direction, the second length being greater than the first length;
wherein leads from the first and second group of leads alternate in a longitudinal direction along the tie bar so that the first and second group of leads are staggered;
wherein the leads of the first and second group of leads each have a respective contact terminal at their distal ends, said contact terminals each having a contact face in a contact plane;
half-etching the first group of leads in a z-direction on a first side thereof, the z-direction being perpendicular to both the transverse and longitudinal directions; and
half-etching the second group of leads in the z-direction on a second side thereof that is opposite the first side.

8. The method of manufacturing a lead frame of claim 7, wherein the first and second group of leads have the same dimensions in the z-direction before said half-etching.

9. The method of manufacturing a lead frame of claim 7, wherein the contact terminals are integrally formed with their respective leads.

10. A method of manufacturing a semiconductor package, the method comprising:
forming a lead frame having tie bars, a first group of leads extending a first length from the tie bars in a transverse direction, a second group of leads extending a second length from the tie bars in the transverse direction, the second length being greater than the first length, wherein leads from the first and second groups of leads alternate in a longitudinal direction along the tie bars so that the first and second groups of leads are staggered, and wherein the second group of leads is displaced from the first group of leads in a z-direction perpendicular to both the transverse and longitudinal directions, the leads of the first and second groups of leads each having a respective contact terminal at their distal ends, said contact terminals each having a contact face in a contact plane, and wherein the tie bars and leads are positioned to form a cavity;
placing a semiconductor die within the cavity;
electrically connecting terminals of the semiconductor die to respective contact terminals of the lead frame;
encapsulating the semiconductor die and lead frame in a packaging material; and
performing singulation operations that separate the leads from their respective tie bars.

11. The method of manufacturing a semiconductor package of claim 10, wherein the step of forming the lead frame includes half-etching the first group of leads in the z-direction on a first side thereof, and half-etching the second group of leads in the z-direction on a second side thereof that is opposite the first side, thereby displacing the first and second groups of leads in the z-direction.

12. The method of manufacturing a semiconductor package of claim 10, wherein the contact faces of the contact terminals remain exposed from the packaging material during said encapsulation.

13. The method of manufacturing a semiconductor package of claim 10, wherein the step of forming the lead frame further comprises forming a die pad within the cavity, and the die placing step comprises placing the semiconductor die on the die pad.

14. The method of manufacturing a semiconductor package of claim 10, wherein the singulation operations are performed with full saw cuts through the lead frames and packaging material.
